(19) United States
(12) Patent Application Publication
(10) Pub. No.: US 2008/0311283 A1
(43) Pub. Date: Dec. 18, 2008

(54) Method of Inspecting and Manufacturing an Integrated Circuit

(75) Inventors: Ingo Brasack, Dresden (DE); Michael Goldberg, Dresden (DE); Kerstin Muehlstaedt, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/763,887

(22) Filed: Jun. 15, 2007

(51) Int. Cl. C23C 14/54

(52) U.S. Cl. 427/10

(57) ABSTRACT

An auxiliary layer is provided over a main surface of a sample, wherein the sample may be a semiconductor substrate. The auxiliary layer may have an essentially plane surface and is transparent or semi-transparent to an inspection radiation with a wave length between, for example, 193 and 800 nm. The sample coated with the auxiliary layer is inspected for defects in the sample via an imaging method that may use coherent radiation. After inspection, the auxiliary layer is removed. Dependent on the defect count, a process of manufacturing integrated circuits may be continued or the sample may be reworked or discarded.

### BACKGROUND

As the dimensions of structures on samples, (e.g., semiconductor wafers and photolithographic masks used in a lithography process to fabricate wafers) continue to shrink and as the allowable size of defects shrinks correspondingly, the requirements related to inspection methods scanning the wafers and masks for defects increase.

Due to the decreasing of the size of defects to be identified a need for higher sensitivity inspection tools arises. In brightfield inspection tools, sensitivity is related to the optical resolution of the respective inspection tool, wherein the optical resolution is given by the wavelength of the light utilized for inspection, the index of refraction and the numerical aperture of the optical system. The numerical aperture of a typical inspection tool is currently in the range of about 0.95 and the cost of increasing the numerical aperture increases drastically in the vicinity of the maximum theoretical value of 1.0. To increase the index of refraction a fluid with a higher index of refraction may be disposed between the surface of the wafer and the optical system. Light sources emitting light with a wave length below 300 nanometers may be used to enhance the resolution of the optical system.

A need exists for a method of manufacturing integrated circuits utilizing optical inspection methods with high sensitivity.

### SUMMARY

A method is described herein to manufacture integrated circuits via optical inspection methods with high sensitivity. The method described herein includes providing an auxiliary layer over a main surface of a sample, wherein the sample may be a semiconductor substrate. The auxiliary layer may have an essentially plane surface and is transparent or semi-transparent to an inspection radiation with a wave length between, for example, 193 and 800 nm. The sample coated with the auxiliary layer is inspected for defects in the sample via an imaging method that may use coherent radiation. After inspection, the auxiliary layer is removed. Dependent on the defect count, a process of manufacturing integrated circuits may be continued or the sample may be reworked or discarded.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of embodiments of the method will be apparent from the following description of the drawings. The drawings are not necessarily to scale. Emphasis is placed upon illustrating the principles. The method is explained in more detail below with reference to accompanying drawings, where:

FIGS. 1A to 1D are schematic cross-sectional views of corresponding sections of a sample for illustrating a method of manufacturing integrated circuits utilizing an optical inspection method via an essentially planar auxiliary layer according to an embodiment.

FIG. 1E is a SEM (scanning electron microscope) image of the sample of FIG. 1C for illustrating the manufacturing method of FIG. 1A to FIG. 1D.

FIGS. 2A to 2C are schematic cross-sectional views of corresponding sections of a sample for illustrating a method of manufacturing integrated circuits utilizing an optical inspection method via a patterned auxiliary layer according to another embodiment.

FIG. 2D is a SEM image of the sample of FIG. 2B for illustrating the manufacturing method of FIG. 2A to FIG. 2C.

FIG. 3A is a SEM image of a sample with patterned auxiliary layer enhancing a bridging type defect for illustrating a method of manufacturing integrated circuits utilizing an optical imaging method according to another embodiment.

FIG. 3B is another SEM image of the sample of FIG. 3A after removal of the patterned auxiliary layer.

FIG. 4 is a simplified flowchart of a method of manufacturing integrated circuits utilizing an optical inspection method according to a further embodiment.

### DETAILED DESCRIPTION

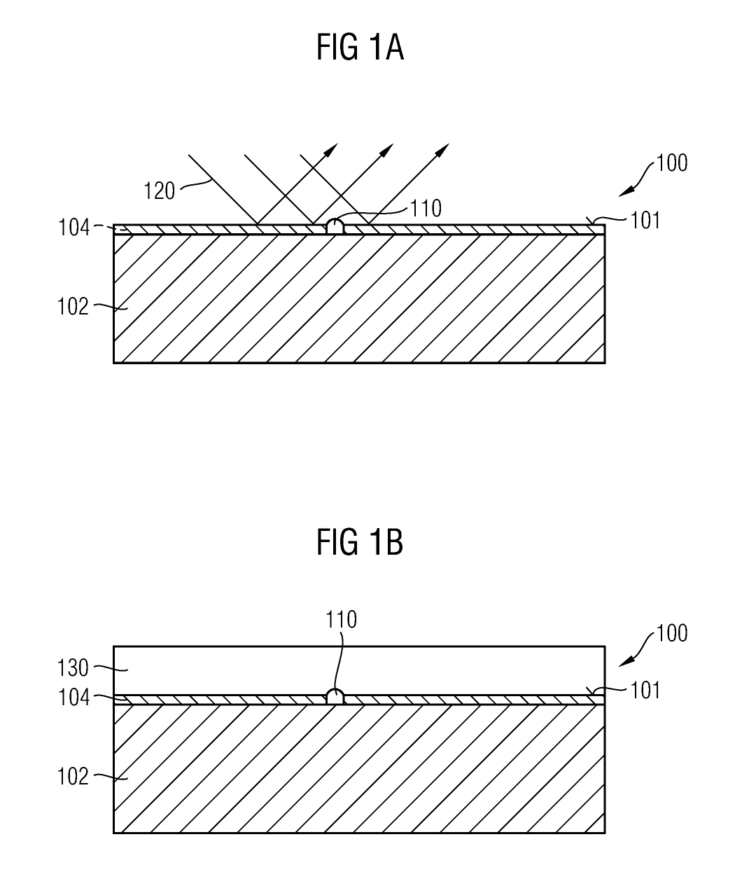

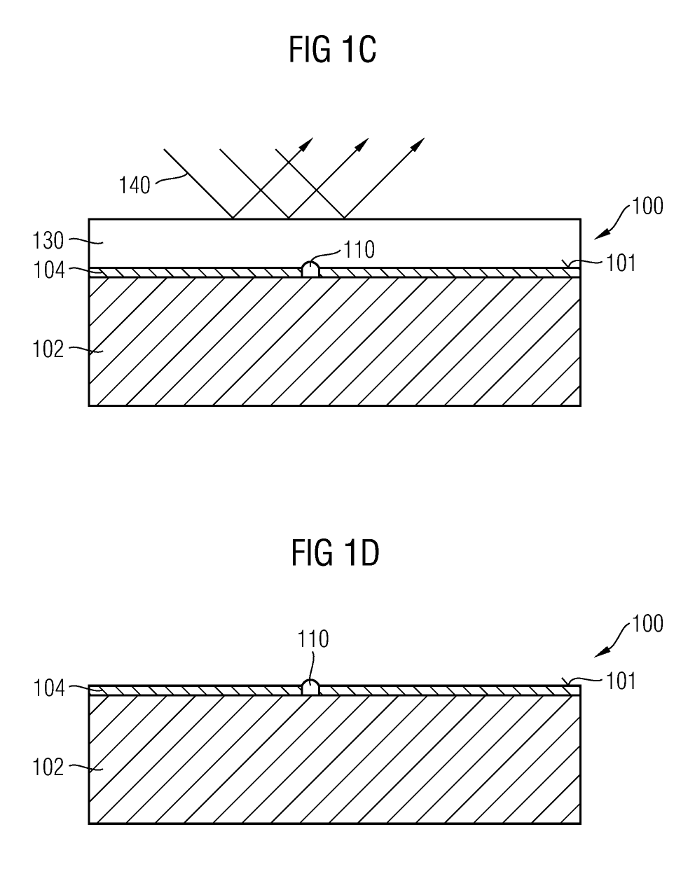

FIGS. 1A to 1D refer to an embodiment of a method of manufacturing integrated circuits utilizing an optical inspection method that utilizes a non-patterned auxiliary layer as an enhancing layer to increase the sensitivity of an optical defect detection system.

FIG. 1A shows a sample 100 comprising a thin liner 104 coating a thick layer 102. The thick layer 102 may at least partially cover, for example, a preprocessed single crystalline silicon wafer or a silicon-on-insulator wafer and may comprise further doped and/or undoped sections and epitaxial semiconductor layers supported by a base conductor or a base insulator. The sample may comprise further structures that have previously been fabricated. The thick layer 102 may be, for example, an aluminum-copper-alloy that is deposited through an electroplating process. On an upper surface of the thick layer 102, FIG. 1A shows a defect 110, which may be, for example, an aluminum droplet resulting from an inhomogeneous electrical field during the deposition process. The thin liner 104 may be a titanium nitride liner, for example. The thin liner 104 may conformally cover the defect 110 or may comprise an inhomogeneity around the defect 110 as illustrated, for example, in FIG. 1A. The exposed top surface of the thin liner 104 forms a main surface 101 of the sample 100. Inspecting the sample 100 via an automated optical defect detection method via an inspection radiation 120 may detect defects of the type of defect 110.

As shown in FIG. 1B, an auxiliary layer 130 is provided on the main surface 101 of the sample 100. The auxiliary layer 130 may be deposited via deposition methods (e.g., CVD (chemical vapor deposition), PVD (physical vapor deposition) or a spin-on-coating-method) which provide a plane, smooth surface with a roughness of, for example, less than 40 nm, for example about 20 nm.

As shown in FIG. 1B, the auxiliary layer 130 essentially levels an underlying topology and does not reproduce the topology of the defect 110 on its exposed surface. However, in another embodiment it may reproduce the topology at least to some extent. According to further examples, the sample 100, the thick layer 102 and the thin liner 104 may be patterned and may form dots and lines on an underlayer, wherein the dots and lines are separated by trenches. The auxiliary layer 130 may be deposited via gap filling deposition methods. The thickness of the auxiliary layer 130 may range from 10 nm to about 1000 nm. The auxiliary layer is transparent or semi-transparent, with a transmittance of at least 0.01, for example, greater than 0.1 or optionally greater than 0.5, to an inspection radiation having a wave length between about 193 nm and about 800 nm.

Referring to FIG. 1C, the sample 100 is inspected for defects via an automated optical defect detection method via the inspection radiation 140, which may be the same as in FIG. 1A. As could be shown by the inventors, the number of defects in the sample 100, for example, of the type of defect 110, detected through the auxiliary layer 130 is significantly increased to an inspection without the auxiliary layer 130.

The auxiliary layer 130 increases the sensitivity of the respective optical defect detection method inspecting the sample and using the inspection radiation 140. If the defects in the sample, i.e., defects beneath the auxiliary layer but not in the auxiliary layer are classified according to their size, it could be shown that in all classes the number of detected defects is significantly increased. The auxiliary layer 130 enhances defects in the sample of the type of defect 110 such that defects in the sample beneath the auxiliary layer that are not detected without auxiliary layer 130 can be detected. Other types of defects may be pinhole-type defects, particle contamination or structural defects.

The material of the auxiliary layer 130 may be, for example, a photoresist, a silicon oxide, a silicate, a silicon nitride, a silicon oxynitride, carbon or any transparent or semi-transparent metal compound. The optical detection method may be one of a bright field inspection, a dark field inspection or a combination of dark field and bright field inspection and may use coherent radiation. According to an embodiment, the optical defect detection method is based upon automated image capture and automated image comparison and/or signal intensity comparison. Depending on the results of the inspection, it can be determined whether the manufacturing of integrated circuits from the sample may be continued, or the sample may be reworked or discarded. If the manufacturing process is continued, the auxiliary layer 130 is removed after inspection, as illustrated in FIG. 1D.

FIG. 1E is a SEM (scanning electron microscope) image showing the defect 110. Due to an inhomogeneous electrical field during deposition, an aluminum droplet with a diameter of 10 to 1000 nm may be formed on the plane top surface of the thick layer 102. According to the embodiment of FIGS. 1A to 1D, the auxiliary layer 130 is a silicon oxynitride layer with a thickness of about 190 nm and an index of refraction of about 1.93.

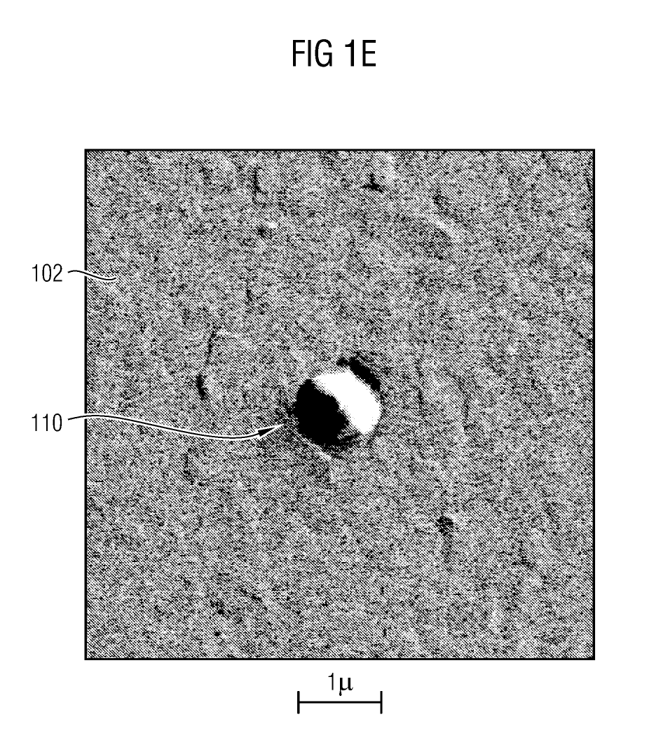

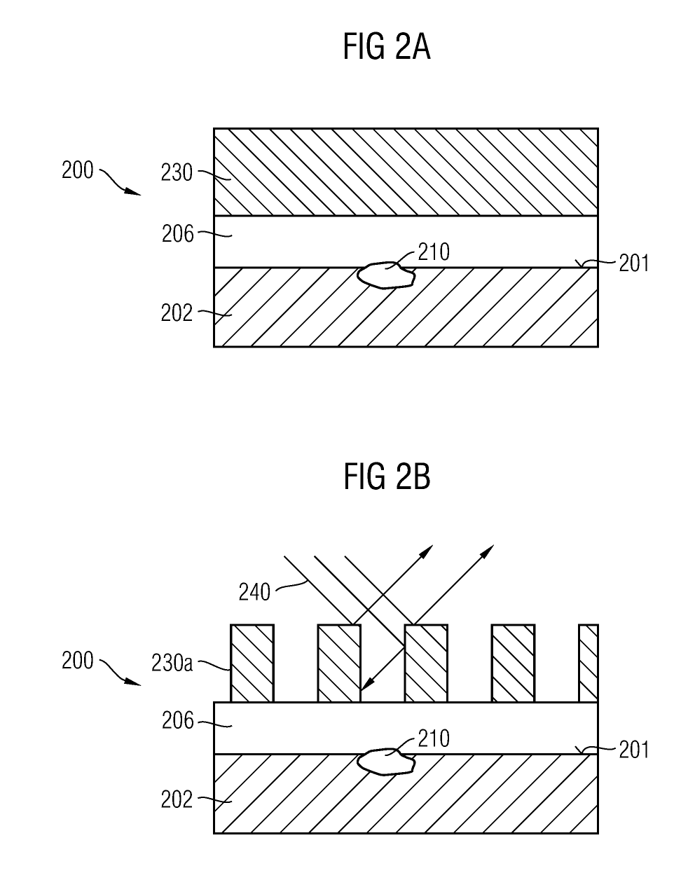

The embodiment according to FIGS. 2A to 2D refers to the enhancing of defects using a patterned auxiliary layer 230.

FIG. 2A shows a sample 200 which may be a preprocessed semiconductor wafer as described with reference to FIG. 1, wherein an underlayer 202 is covered by a transparent or semitransparent intermediate layer 206. A defect 210 may be embedded in the underlayer 202. According to other embodiments, the defect 210 may be located on the surface of the underlayer 202. The material of the underlayer 202 is for example a non-transparent material, for example silicon. The intermediate layer 206 may be a silicon dioxide layer with a thickness of about 120 nm and an index of refraction of 1.46. The underlayer 202 is part of a sample 200 with a main surface 201. An auxiliary layer 230 is provided on the intermediate layer 206. The auxiliary layer 230 may be, for example, a photoresist configured to support an ArF lithographic process. The thickness of the auxiliary layer 230 is for example 200 nm. The index of refraction may be about 1.46. The transmittance may be greater than 0.5.

As illustrated in FIG. 2B, the auxiliary layer 230 may be patterned to expose sections of the intermediate layer 206. Then, the sample 200 is inspected for defects 210 via an optical defect detection method via an inspection radiation 240 with a wavelength between 193 nm and about 800 nm.

According to FIG. 2C, after inspection, the pattern of the patterned auxiliary layer 230a is transferred into the intermediate layer 206 and the patterned auxiliary layer 230a is removed. A second inspection for defects may be performed using an inspection radiation 220, which may be, for example, equivalent to the inspection radiation 240 of the first inspection. The first inspection may be an optical defect detection method, for example, a dark field inspection via an automated image capture and image comparison. The second inspection method may be, for example, a bright field optical defect detection method. The inventors could show that through the first inspection according to FIG. 2B, more defects of the type of defect 210 can be detected as through the second inspection according to FIG. 2C. The patterned auxiliary layer 230a may enhance defects of the type of defect 210 in or on the surface of the sample 200 such that the sensitivity of the first inspection is higher than that of the second inspection.

FIG. 2D shows a defect of the type of defect 210 in a SEM image. The bright lines correspond to the patterned auxiliary layer 230a and the dark lines correspond to the trenches between them that expose sections of the intermediate layer 206. Within the dotted circle, the SEM image shows two bright dots extending into the dark lines. These bright dots are also detectable via an optical defect detection method via, for example automated image capture, automated image comparison, and a coherent radiation with a wave length between 220 nm and 500 nm. The defect 210 is typically not detectable after patterning the intermediate layer 206 and removing the patterned auxiliary layer 230a, which in this example is effective as a photoresist mask.

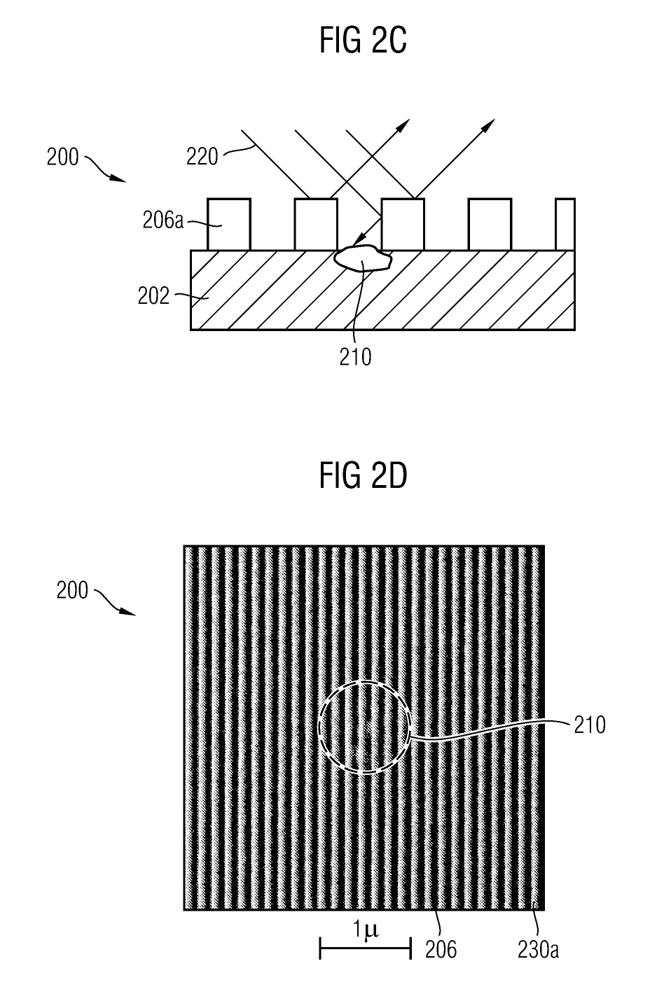

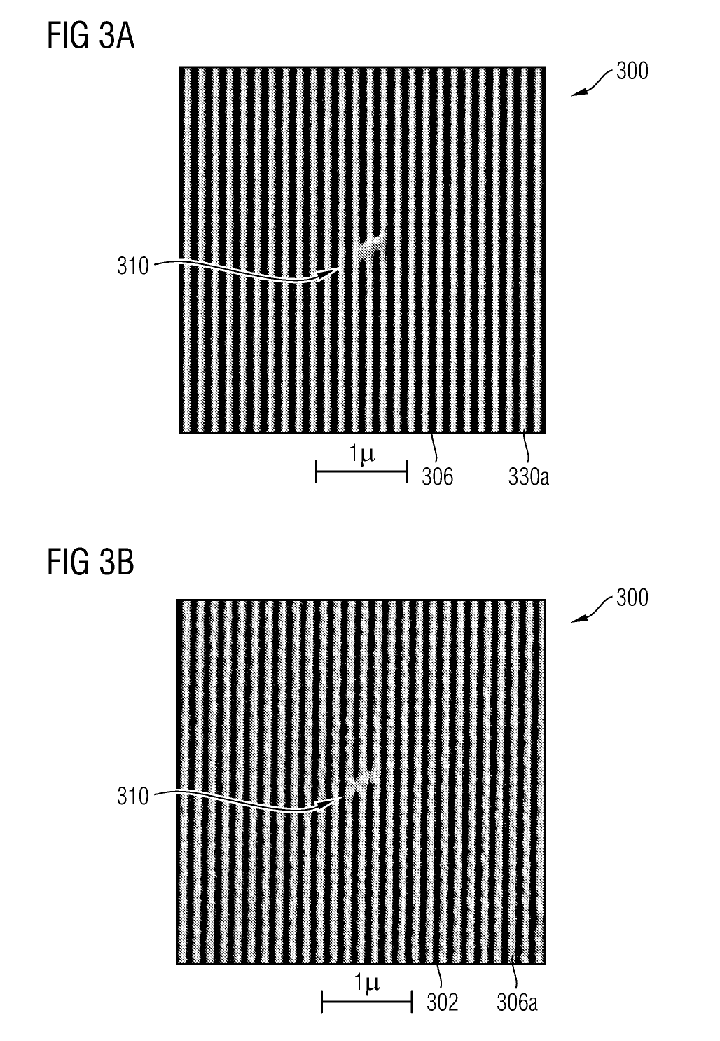

FIGS. 3A to 3B refer to a further defect pattern, for which the sensitivity of the optical defect detection method may be increased though an auxiliary layer according to an exemplary embodiment.

The sample 300 may be similar to that of FIG. 2A to FIG. 2C, wherein the bright lines 330a correspond to a patterned auxiliary layer 330a, and wherein the dark lines refer to trenches exposing the intermediate layer 306. Defect 310 is a bridging defect which may be easily detected by an optical defect detection method via an inspection radiation of a wave length between 193 nm and 800 nm and which is based upon automated image capture and image comparison and/or signal intensity comparison.

FIG. 3B is a further SEM image of the same sample 300 of FIG. 3A after transferring the pattern of the auxiliary layer 330a into the intermediate layer 306 to expose sections of the underlayer 302. Though, in this example, the bridging defect 310 is also visible in the SEM image of FIG. 3B, the sensitivity to defects in or on the main surface of the sample is significantly decreased compared to the configuration according to FIG. 3A.

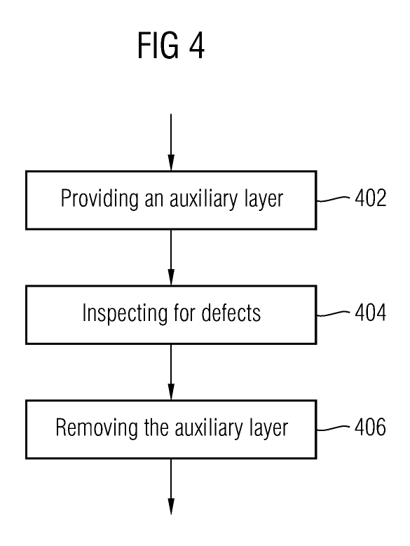

FIG. 4 is a flowchart illustrating a method of manufacturing integrated circuits via an optical inspection method according to a further embodiment. An auxiliary layer is provided on a main surface of a sample (402), wherein the sample may be, for example, a wafer. The auxiliary layer may have an essentially plane surface and is transparent or semi-transparent to an inspection radiation with a wavelength between, for example, 193 nm and 800 nanometers. The sample coated with the auxiliary layer is inspected for defects in the sample (404) via an automated optical defect detection method via the inspection radiation, which may be, for example, a coherent radiation. After inspection, the auxiliary layer is removed (406).

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of manufacturing an integrated circuit, the method comprising:
providing an auxiliary layer over a main surface of a sample, the auxiliary layer having a substantially planar surface and including sections that are at least semi-transparent to an inspection radiation with a wavelength in the range between 193 nm and 800 nm, inclusive;
inspecting the sample for defects via an optical defect detection method via the inspection radiation; and
subsequently removing the auxiliary layer.

2. The method of claim 1, further comprising:
patterning the auxiliary layer to expose sections of an underlayer of the sample, prior to inspecting the sample.

3. The method of claim 1, further comprising:
providing an intermediate layer on the main surface of the sample prior to providing the auxiliary layer, the intermediate layer being at least semi-transparent to the inspection radiation.

4. The method of claim 1, wherein the auxiliary layer is deposited via a gap filling deposition method.

5. The method of claim 1, wherein the optical defect detecting method is a method selected from the group including: a bright field inspection, a dark field inspection or a combination of dark and bright field inspections.

6. The method of claim 1, wherein the auxiliary layer comprises at least one material selected from the group including: a photoresist, a silicon oxide, a silicate, a silicon nitride, a silicon oxynitride, a carbon and any transparent or semi-transparent metal compound.

7. The method of claim 1, wherein the thickness of the auxiliary layer is between 5 nm and 1000 nm, inclusive.

8. The method of claim 1, wherein the inspection radiation is a coherent radiation.

9. The method of claim 1, wherein a roughness of the auxiliary layer is less than 40 nm.

10. The method of claim 1, wherein the optical defect detection method includes at least one procedure selected from the group including: automated image capture, image comparison and signal intensity comparison.

11. The method of claim 1, wherein the auxiliary layer is completely removed after inspection.

12. The method of claim 1, wherein the entire auxiliary layer is at least semi-transparent to the inspection radiation.

13. The method of claim 1, wherein the sample is inspected with the auxiliary layer being non-patterned and covering the entire main surface of the sample.

14. The method of claim 1, further comprising:
determining, according to a result of the inspection, whether the manufacturing of integrated circuits from the sample may be continued, or the sample may be reworked or discarded; and
in the event it is determined that manufacturing of integrated circuits from the sample may be continued, continuing to manufacture at least one integrated circuit from the sample.
